(19) United States
(12) Patent Application Publication
(10) Pub. No.: US 2005/0064647 A1
(43) Pub. Date: Mar. 24, 2005

(54) Wire, method of manufacturing the wire, and electromagnet using the wire

(75) Inventors: Chikara Manabe, Nakai-machi (JP); Kazunori Anazawa, Nakai-machi (JP); Masaki Hirakata, Nakai-machi (JP); Kentaro Kishi, Nakai-machi (JP); Taishi Shigematsu, Nakai-machi (JP); Miho Watanabe, Nakai-machi (JP); Takashi Isozaki, Nakai-machi (JP); Hiroyuki Watanabe, Nakai-machi (JP); Shigeki Ooma, Nakai-machi (JP); Shinsuke Okada, Nakai-machi (JP)

Correspondence Address: OLIFF & BERRIDGE, PLC, P.O. BOX 19928, ALEXANDRIA, VA, 22320, US

(73) Assignee: FUJI XEROX CO., LTD, Minato-ku (JP)

(21) Appl. No.: 10/766,879

(22) Filed: Jan. 30, 2004

(30) Foreign Application Priority Data
Sep. 24, 2003 (JP) 2003-332251

(51) Int. Cl. H01L 21/8238

(52) U.S. Cl. 438/222

(57) ABSTRACT

To provide a wire excellent in electrical characteristics or in mechanical characteristics. A wire is constructed at least by a carbon nanotube structure layer (1) in which plural carbon nanotubes mutually cross-link to configure a mesh structure on the surface of a substrate (2). A method of manufacturing the wire includes: an applying step of applying to the surface of the substrate (2) a liquid solution containing a carbon nanotube having a functional group; and a step of curing the liquid solution after the application. An electromagnet scarcely causing a loss is formed using the wire.

### FIELD OF THE INVENTION AND RELATED ART STATEMENT

The present invention relates to a wire using a carbon nanotube structure, a method of manufacturing the wire, and an electromagnet using the wire.

Carbon nanotubes (CNTs), with their unique shape and characteristics, are being considered for various applications. Carbon nanotubes have a tubular shape of one-dimensional nature which is obtained by rolling one or more graphene sheets composed of six-membered rings of carbon atoms into a tube. Those that are formed from one graphene sheet are called single-wall nanotubes (SWNTs) while those that are formed from graphene sheet layers are called multi-wall nanotubes (MWNTs). SWNTs are about 1 nm in diameter whereas multi-wall carbon nanotubes measure several tens nm in diameter, and both are far thinner than their predecessors, which are called carbon fibers.

One of the characteristics of carbon nanotubes is that the aspect ratio of length to diameter is very large since the length of carbon nanotubes is on the order of micrometers. Carbon nanotubes are unique in their extremely rare nature of being both metallic and semi-conductive, owing to the fact that six-membered rings of carbon atoms in carbon nanotubes are arranged into a spiral. In addition, the electric conductivity of carbon nanotubes is very high and allows a current flow of 100 MA/cm² or more in terms of current density.

Carbon nanotubes excel not only in electrical characteristics but also in mechanical characteristics. That is, carbon nanotubes have distinct toughness, as attested by their Young's modulus exceeding 1 TPa, although they have extreme lightness resulting from being formed solely of carbon atoms, and high elasticity and resiliency resulting from their cage structure. Having such various and excellent characteristics, carbon nanotubes are very appealing as industrial materials.

Applied researches that exploit the excellent characteristics of carbon nanotubes have been made extensively. To give a few examples, carbon nanotubes are added as a resin reinforcer or as a conductive composite material while another research utilizes carbon nanotubes as a probe of a scanning probe microscope. Carbon nanotubes have also been utilized as minute electron sources, field emission electronic devices, and flat displays. An application that is being developed is to use carbon nanotubes as a container for hydrogen storage.

Of those various applications of carbon nanotubes, applications as electronic materials and electronic devices are particularly attracting attention.

For example, JP 2002-313147 A discloses a flat cable in which conductive ways are printed on one side or both sides of a film-shaped insulating substrate with a conductive paste prepared by kneading a conductive filler, which is a carbon nanotube, with a binder-use polymer.

### SUMMARY OF THE INVENTION

However, those carbon nanotubes merely contact each other in a film. The contact condition of the carbon nanotubes varies owing to bending or the like, and the mechanical strengths and electrical characteristics of the carbon nanotubes fluctuate. Therefore, the carbon nanotubes are unable to exert sufficient performance.

In addition, a loading weight of carbon nanotubes must be increased to improve an electric conductivity. In this case, however, the amount of binders decreases to result in reduced mechanical strength of a cable itself. In particular, in a state where each carbon nanotube is isolated in a binder, the carbon nanotube merely functions as a conductive filler. Thus, characteristics of the carbon nanotube itself resulting from a graphene sheet structure such as electric conductivity and mechanical strength can not be sufficiently exerted.

Therefore, the present invention is intended to solve the above problems in the prior art. More specifically, an object of the present invention is to provide a wire and an electromagnet which can effectively utilize characteristics of a carbon nanotube structure.

The above object is attained by the present invention as described below. That is, a wire according to the present invention is characterized by including a core wire of a carbon nanotube structure in which functional groups bonded to plural carbon nanotubes are chemically bonded and mutually cross-linked to configure a mesh structure.

The wire of the present invention uses a core wire of a carbon nanotube structure in which plural carbon nanotubes form a mesh structure via multiple cross-linked sites. Therefore, electrical and mechanical characteristics do not become unstable depending on the contact condition of the carbon nanotubes unlike the case where a mere filling film of carbon nanotubes is used as a wire. Thus, characteristics peculiar to a carbon nanotube can be stably exerted.

Furthermore, in the case where the wire of the present invention is used as a lead wire, electrical characteristics can be stably obtained because the carbon nanotubes mutually cross-link. In the case where the wire of the present invention is used for applications excluding a lead wire, mechanical characteristics such as bending endurance can be improved as compared to those of a filling film of carbon nanotubes because the carbon nanotubes mutually cross-link.

The carbon nanotube structure is preferably formed by curing a liquid solution containing plural carbon nanotubes to which functional groups are bonded, and by chemically bonding together the plural functional groups bonded to the carbon nanotubes to form a cross-linked site.

Of those, a first structure preferable as the cross-linked site is a structure obtained by cross-linking together the plural functional groups with a crosslinking agent in the liquid solution. More preferably, the crosslinking agent is not self-polymerizable.

If the carbon nanotube structure is formed by curing a liquid solution as described above, the cross-linked site in which the carbon nanotubes cross-link each other can form a cross-linked structure in which residues remaining after the cross-linking reaction of the functional groups are linked to each other with a liking group that is a residue remaining after the cross-linking reaction of the crosslinking agent.

If the crosslinking agent has a property of polymerizing with other crosslinking agents (self polymerizability), the liking group contains a polymer in which two or more crosslinking agents are linked to each other in some cases. In such cases, a substantial density of the carbon nanotubes in the carbon nanotube structure decreases, and sufficient electric conductivity and mechanical strength of a wire may not be obtained.

On the other hand, if the cross-linking agent is not self-polymerizable, a gap between each of the carbon nanotubes can be controlled to a size of a cross-linking agent residue used. Therefore, a desired network structure of carbon nanotubes can be obtained with high duplicability. Further, by reducing the size of the cross-linking agent residue, a gap between each of the carbon nanotubes can be configured in an extremely close state electrically and physically. In addition, carbon nanotubes in the structure can be densely structured.

Therefore, if the cross-linking agent is not self-polymerizable, the carbon nanotube structure of the present invention can exhibit inherent electrical characteristics and mechanical characteristics of the carbon nanotubes in an extremely high level. In the present invention, “self-polymerizable” refers to a property of which the cross-linking agents may prompt a polymerization reaction with one another in the presence of other components such as water or without the presence of other components. On the other hand, “not self-polymerizable” means without such a property.

If a not self-polymerizable cross-linking agent is selected, a cross-linked site, where carbon nanotubes are cross-linked to one another, in the coat of the present invention has primarily an identical cross-linking structure. Furthermore, the coupling group preferably employs a hydrocarbon as its skeleton, and the number of carbon atoms of the skeleton is preferably 2 to 10. Reducing the number of carbon atoms can shorten the length of a cross-linked site and sufficiently narrow a gap between carbon nanotubes as compared to the length of a carbon nanotube itself. As a result, a carbon nanotube structure of a mesh structure composed substantially only of carbon nanotubes can be obtained.

Examples of the functional group include —OH, —COOH, —COOR (R is a substituted or unsubstituted hydrocarbon group), —COX (x is a halogen atom), —NH₂, and —NCO. A selection of at least one functional group selected from the above group is preferable, and in such a case, a cross-linking agent, which may prompt a cross-linking reaction with the selected functional group, is selected.

Further, examples of the preferable cross-linking agent include polyol, polyamine, polycarboxylic acid, polycarboxylate, polycarboxylic acid halide, polycarbodiimide, and polyisocyanate. A selection of at least one cross-linking agent selected from the above group is preferable, and in such a case, a functional group, which may prompt a cross-linking reaction with the selected cross-linking agent, is selected.

At least one functional group and one cross-linking agent are selected respectively from the group exemplified as the preferable functional group and the group exemplified as the preferable cross-linking agent, so that a combination thereof may prompt a cross-linking reaction with one another.

Examples of the particularly preferable functional group include —COOR (R is a substituted or unsubstituted hydrocarbon group). Introduction of a carboxyl group to carbon nanotubes is relatively easy, and the resultant substance (carbon nanotube carboxylic acid) is highly reactive. Therefore, after the formation of the substance, it is relatively easy to esterify the substance to convert its functional group into —COOR (R is a substituted or unsubstituted hydrocarbon group), and such functional group easily reacts in a cross-linking reaction and is suitable for formation of a coat.

A polyol can be exemplified as the crosslinking agent corresponding to the functional group. A polyol is cured by a reaction with —COOR (where R represents a substituted or unsubstituted hydrocarbon group), and forms a robust cross-linked substance with ease. Among polyols, each of glycerin and ethylene glycol reacts with the above functional groups well. Moreover, each of glycerin and ethylene glycol itself has high biodegradability, and applies a light load to an environment.

In the cross-linked site in which plural carbon nanotubes mutually cross-link, the functional group is —COOR (where R represents a substituted or unsubstituted hydrocarbon group). The cross-linked site is —COO(CH₂)₂OCO— in the case where ethylene glycol is used as the crosslinking agent. In the case where glycerin is used as the crosslinking agent, the cross-linked site is —COOCH₂CHOHCH₂OCO— or —COOCH₂CH(OCO—)CH₂OH— if two OH groups contribute to the cross-linking, and the cross-linked site is —COOCH₂CH(OCO—)CH₂OCO— if three OH groups contribute to the cross-linking. The chemical structure of the cross-linked site may be a chemical structure selected from the group consisting of the above four structures.

A second structure preferable as the structure of the cross-linked site is a structure formed by chemical bonding of plural functional groups. More preferably, a reaction that causes the chemical bonding is any one of dehydration condensation, a substitution reaction, an addition reaction, and an oxidation reaction.

In the carbon nanotube structure, carbon nanotubes forms a cross-linked site by chemically bonding together functional groups bonded to the carbon nanotubes, to thereby form a mesh structure. Therefore, the size of the cross-linked site for bonding the carbon nanotubes becomes constant depending on the functional group to be bonded. Since a carbon nanotube has an extremely stable chemical structure, there is a low possibility that functional groups or the like excluding a functional group to modify the carbon nanotube are bonded to the carbon nanotube. In the case where the functional groups are chemically bonded together, the designed structure of the cross-linked site can be obtained, and the carbon nanotube structure can be homogeneous.

Furthermore, the functional groups are chemically bonded together, so that the length of the cross-linked site between the carbon nanotubes can be shorter than that in the case where the functional groups are cross-linked with a crosslinking agent. Therefore, the carbon nanotube structure is dense, and tends to readily produce an effect peculiar to a carbon nanotube.

In the carbon nanotube structure of the present invention, plural carbon nanotubes form a mesh structure via multiple cross-linked sites. As a result, excellent characteristics of a carbon nanotube can be stably utilized unlike a material such as a mere carbon nanotube dispersion film or a resin dispersion film in which carbon nanotubes accidentally contact each other and are substantially isolated from each other.

The chemical bonding of plural functional groups is preferably one selected from —COOCO—, —O—, —NHCO—, —COO—, and —NCH— in a condensation reaction. The chemical bonding is preferably at least one selected from —NH—, —S—, and —O— in a substitution reaction. The chemical bonding is preferably —NHCOO— in an addition reaction. The chemical bonding is preferably —S—S— in an oxidation reaction,

Examples of the functional group to be bonded to a carbon nanotube prior to the reaction include —OH—, —COOH, —COOR (where R represents a substituted or unsubstituted hydrocarbon group), —X, —COX (where X represents a halogen atom), —SH, —CHO, —OSO₂CH₃, —OSO₂(C₆H₄)CH₃—NH₂, and —NCO. It is preferable to select at least one group from the group consisting of the above groups.

Particularly preferable examples of the functional group include —COOH. A carboxyl group can be relatively easily introduced into a carbon nanotube. In addition, the resultant substance (a carbon nanotube carboxylic acid) has high reactivity, easily causes a condensation reaction by using a dehydration condensation agent such as N-ethyl-N′-(3-dimethylaminopropyl)carbodiimide, and is thus suitable for forming a coat.

In order to increase the electric conductivity of the wire, the plural carbon nanotubes are preferably multi-wall carbon nanotubes with high electric conductivity. This is because, when functional groups are bonded, a graphene sheet structure as an internal layer is destroyed to a small extent and characteristics peculiar to a nanotube hardly deteriorate.

(Manufacturing Method)

Next, a method of manufacturing a wire of the present invention is characterized by including: an applying step of applying to the surface of a substrate a liquid solution containing plural carbon nanotubes to which functional groups are bonded; and a cross-linking step of chemically bonding together the functional groups to form a core wire layer of a carbon nanotube structure in which the plural carbon nanotubes mutually cross-link to configure a mesh structure.

In the present invention, first, in the applying step of applying to the surface of a substrate a liquid solution containing plural carbon nanotubes to which functional groups are bonded (hereinafter, referred to as “cross-lnking application liquid” in some cases), the liquid solution is applied to the whole surface of the substrate or a part of the surface of the substrate. Then, in the subsequent cross-linking step, the liquid solution after the application is cured to form a carbon nanotube structure in which the plural carbon nanotubes mutually cross-link via chemical bonding between the functional groups to configure a mesh structure. Passing those two steps can stabilize the structure itself of the carbon nanotube structure on the substrate.

In forming chemical bonding between functional groups, a first method preferable for forming a cross-linked site is a method of cross-linking the functional groups with a crosslinking agent in the liquid solution. More preferably, the crosslinking agent is not self-polymerizable.

In the method of manufacturing a wire of the present invention, examples of the functional group for forming the cross-linked site using the crosslinking agent include —OH, —COOH, —COOR (R is a substituted or unsubstituted hydrocarbon group), —COX (X is a halogen atom), —NH₂, and —NCO. A selection of at least one functional group selected from the above group is preferable, and in such a case, a cross-linking agent, which may prompt a cross-linking reaction with the selected functional group, is selected.

Further, examples of the preferable cross-linking agent include polyol, polyamine, polycarboxylic acid, polycarboxylate, polycarboxylic acid halide, polycarbodiimide, and polyisocyanate. A selection of at least one cross-linking agent selected from the above group is preferable, and in such a case, a functional group, which may prompt a cross-linking reaction with the selected cross-linking agent, is selected.

At least one functional group and one cross-linking agent are selected respectively from the group exemplified as the preferable functional group and the group exemplified as the preferable cross-linking agent, so that a combination thereof may prompt a cross-linking reaction with one another.

Particularly preferable examples of the functional group include —COOR (where R represents a substituted or unsubstituted hydrocarbon group). A carboxyl group can be relatively easily introduced into a carbon nanotube, and the resultant substance (carbon nanotube carboxylic acid) has high reactivity. Therefore, after the formation of the substance, it is relatively easy to esterify the substance to convert its functional group into —COOR (where R represents a substituted or unsubstituted hydrocarbon group). The functional group easily causes a cross-linking reaction, and is suitable for the formation of a coat.

In addition, a polyol may be the crosslinking agent corresponding to the functional group. A polyol is cured by a reaction with —COOR (where R represents a substituted or unsubstituted hydrocarbon group), and forms a robust cross-linked substance with ease. Among polyols, each of glycerin and ethylene glycol reacts with the above functional groups well. Moreover, each of glycerin and ethylene glycol itself has high biodegradability, and applies a light load to an environment.

Further, a preferable second method of forming a cross-linked site is a method of chemically bonding plural functional groups together.

From the above, a size of the cross-linked site, which bonds the carbon nanotubes together, becomes constant depending on the functional group to bond. A carbon nanotube has an extremely stable chemical structure, so that a possibility of bonding of functional groups or the like, other than the functional groups intended for a modification, is low. When chemically bonding the functional groups together, a structure of the designed cross-linked portion can be obtained, providing a homogeneous carbon nanotube structure.

Further, functional groups are chemically bonded together and thus a length of the cross-linked portion between the carbon nanotubes can be shortened compared to the case of cross-linking the functional groups together using a cross-linking agent. Therefore, the carbon nanotube structure becomes dense, and effects peculiar to carbon nanotubes are easily obtained.

Examples of a particularly preferable reaction, which chemically bonds the functional groups together, include a condensation reaction, a substitution reaction, an addition reaction, and an oxidative reaction.

In a method of manufacturing a wire of the present invention, the preferable functional group includes: at least one functional group selected from the group consisting of —COOR (R is a substituted or unsubstituted hydrocarbon group), —COOH, —COX (X is a halogen atom), —OH, —CHO—, and —NH₂ for the condensation reaction; at least one functional group selected from the group consisting of —NH₂, —X (X is a halogen atom), —SH, —OH, —OSO₂CH₃, and —OSO₂(C₆H₄)CH₃ for the substitution reaction; at least one functional group selected from the group consisting of —OH and —NCO for the addition reaction; and —SH for the oxidative reaction.

In a method of manufacturing a wire of the present invention, a molecule containing the functional groups may be bonded to carbon nanotubes to be chemically bonded as the exemplified functional group portion to configure the cross-linked site.

If the reaction is a dehydration condensation, a condensing agent is preferably added. Further, the preferable functional group is at least one functional group selected from the group consisting of —COOR (R is a substituted or unsubstituted hydrocarbon group), —COOH, —COX (X is a halogen atom), —OH, —CHO, and —NH₂.

As the functional group specifically used for the condensation reaction, —COOH is particularly preferably used. Introduction of a carboxyl group to carbon nanotubes is relatively easy. Moreover, the resultant substance (carbon nanotube carboxylic acid) is highly reactive. Therefore, introduction of functional groups for forming a mesh structure to multiple places of one carbon nanotube is easy. In addition, the functional group easily reacts in a condensation reaction, thus being suitable for a formation of the carbon nanotube structure.

In the method of manufacturing a wire of the present invention, the liquid solution to be used in the applying step may further contain a solvent. The crosslinking agent can also serve as the solvent depending on the kind of the crosslinking agent.

### BRIEF DESCRIPTION OF THE DRAWINGS

Preferred embodiments of the present invention will be described in detail based on the following figures, wherein:

FIG. 1 is a schematic diagram showing an embodiment of a wire of the present invention;

FIG. 2 is a schematic diagram showing a manufacturing unit for the wire of the present invention;

FIGS. 3(A) and 3(B) are schematic diagrams each showing an embodiment of an electromagnet of the present invention;

FIG. 4 is a reaction scheme for the synthesis of a carbon nanotube carboxylic acid in (Addition Step) of Embodiment 1;

FIG. 5 is a reaction scheme for esterification in (Addition Step) of Embodiment 1;

FIG. 6 is a reaction scheme for cross-linking by an ester exchange reaction in (Cross-linking Step) of Embodiment 1; and

FIG. 7 is a graph showing measurements of current-voltage characteristics for a carbon nanotube structure layer formed in Embodiment 1.

### DETAILED DESCRIPTION OF THE PREFERRED EMBODIMENTS

Hereinafter, each of a wire, an electromagnet, and a manufacturing method therefor of the present invention will be described in detail and specifically through the description of the embodiments.

[Wire]

A wire of the present invention is characterized by being constructed by a carbon nanotube structure in which plural carbon nanotubes mutually cross-link to configure a mesh structure.

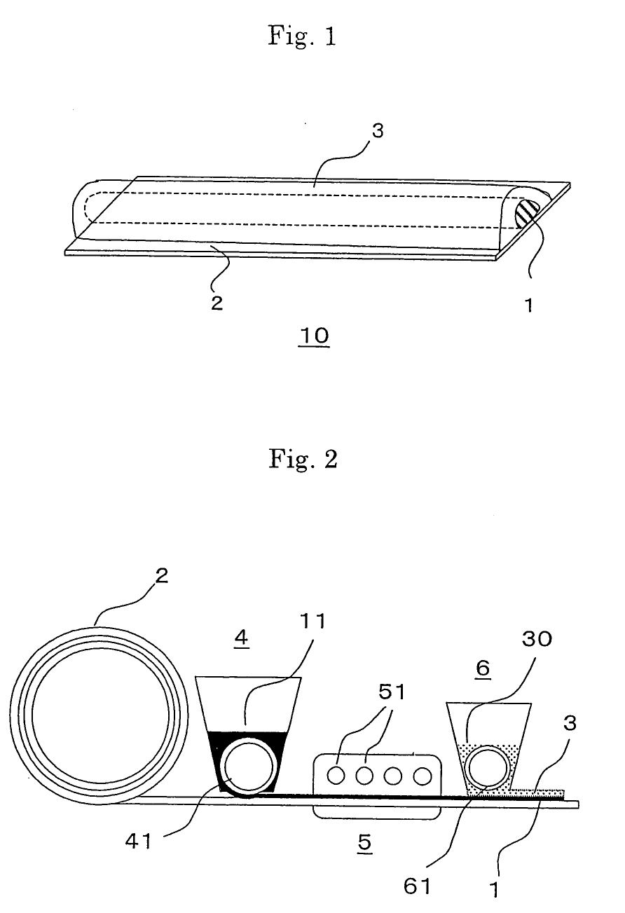

FIG. 1 shows an example of a configuration of a wire. A wire 10 is prepared by fabricating a nanotube structure 1 to serve as a core wire in a linear shape to an insulating substrate 2 (for instance, a Kapton® (polyimide) tape). An insulating resin coating 3 is applied to the nanotube structure.

In particular, the substrate of the wire of the present invention preferably has plasticity or flexibility and insulating property. A carbon nanotube structure layer formed on the surface of the substrate has a cross-linked structure. Therefore, even if the wire is bent and deformed, the possibility that the carbon nanotube structure layer on the surface ruptures is low, and degradation in device performance due to deformation is reduced. Examples of a substrate having plasticity or flexibility and insulating property include various resins such as polyethylene, polypropylene, polyvinyl chloride, polyamide, and polyimide.

Although the nanotube structure 1 does not necessarily require a coating, coating the nanotube structure with a resin that is insulating or conductive, and is elastic prevents the characteristics of the carbon nanotube structure from deteriorating.

<Carbon Nanotube Structure>

In the present invention, “carbon nanotube structure” refers to a configuration having a mesh structure in which plural carbon nanotubes are cross-linked to one another. As long as a structure of carbon nanotubes can be formed to configure a mutually cross-linked mesh structure, the carbon nanotube structure may be formed through any method. However, with a structure manufactured through a method of manufacturing a wire of the present invention described later, it can be produced easily, and a high-performance wire can be obtained, besides, equalization and control of character are easy.

A first structure of the carbon nanotube structure used as a wire in the wire of the present invention manufactured through a method of manufacturing a wire of the present invention described later is obtained through the steps of:
curing a liquid solution containing carbon nanotubes that have a functional group, and a cross-linking agent that prompts a cross-linking reaction with the functional group (cross-linking application liquid); and
forming a cross-linked site through a cross-linking reaction of the functional group, which the carbon nanotubes have, and the cross-linking agent. Further, a second structure of the present invention is obtained by forming the cross-linked site through chemical bonding the functional groups of the carbon nanotubes together.
   <Base Body>

In the present invention, the term base body means an object where a carbon nanotube structure is formed. A base body is a member supplied with a liquid solution in which carbon nanotubes modified with functional groups are mixed with a necessary additive in order to form a carbon nanotube structure. A base body may be like a mold which is separated from the carbon nanotube structure after formation of the carbon nanotube structure is completed, or may serve as a substrate constituting a part of a device that uses the carbon nanotube structure. In the present invention, a base body is not limited to a flat shape but can have any surface shape including spherical, curved, convexed or concaved, and amorphous.

When forming a carbon nanotube structure into a layer, the shape of a base body determines a course to take. If the shape of a base body allows, a carbon nanotube structure layer can be patterned directly on a surface of the base body. If not, a base body and a patterned carbon nanotube structure layer carried on the base body are together pasted onto a second base body, or the patterned carbon nanotube structure layer alone is transferred to the second base body. (Those are examples and there are other courses though not described here.)

There is no particular limitation on material of a base body. In addition to various materials conventionally used in substrates of electronic devices (such as a silicon wafer or a zinc oxide substrate), a diversity of resin materials and inorganic materials can be used for a base body without a problem. In general, a substrate having an insulating surface is chosen as a base body. However, a base body that is not insulative (a conductive or semi-conductive base body) may be employed depending on the function of a carbon nanotube structure layer to be formed.

In particular, a carbon nanotube structure of the present invention can be manufactured with ease even when a base body is a plastic or flexible substrate as will be described later. In addition, even if this substrate is bent and deformed, the risk of breaking a carbon nanotube structure layer that is formed on a surface of the substrate is small because of the cross-linking structure of the carbon nanotube structure layer. Thus, degradation of the performance of a device that uses the carbon nanotube structure due to the deformation is prevented. Also, chemical bonding between functional groups in the carbon nanotube structure makes characteristics of the carbon nanotube structure homogeneous. Examples of plastic or flexible substrates include substrates formed from various resins such as polyethylene, polypropylene, polyvinyl chloride, polyamide, and polyimide.

<Carbon Nanotube Structure Layer>

In the present invention, the term carbon nanotube structure layer means a layer in which plural carbon nanotubes constitute a mesh structure by being chemically bonded to one another through cross-linked sites formed from chemical bonds between plural functional groups that are bonded, at least on one end, to different carbon nanotubes out of the plural carbon nanotubes. Any method can be employed to form a carbon nanotube structure layer as long as the method is capable of forming a layer of carbon nanotubes that constitute a mesh structure by being cross-linked to one another through chemical bonding between functional groups. However, a carbon nanotube structure manufacturing method of the present invention which is described later is preferable since the manufacture is easy with the method. This manufacturing method is also capable of providing at low cost a high performance carbon nanotube structure whose characteristics are easy to control and uniformize.

The carbon nanotube structure layer manufactured by the carbon nanotube structure manufacturing method of the present invention, which is described later, to be used as a carbon nanotube structure of the present invention is formed by curing a liquid solution (cross-linking application liquid) that contains carbon nanotubes having functional groups and, if necessary, an additive for forming chemical bonds between the functional groups. As the liquid solution is cured, the functional groups of the carbon nanotubes react with one another to form cross-linking sites.

The carbon nanotube structure layer in the wire of the present invention is described below by way of an example according to the carbon nanotube structure manufacturing method. If not particularly described, any structure of the cross-linked site may be adapted for the item.

(Carbon Nanotube)

Carbon nanotubes, which are the main component in the present invention, may be single-wall carbon nanotubes or multi-wall carbon nanotubes having two or more layers. Whether one or both types of carbon nanotubes are used (and, if only one type is to be used, which type is chosen) is decided appropriately taking into consideration the use of the wire or the cost.

Carbon nanotubes in the present invention include ones that are not exactly shaped like a tube, such as a carbon nanohorn (a horn-shaped carbon nanotube whose diameter is continuously increased from one end toward the other end) which is a variant of a single-wall carbon nanotube, a carbon nanocoil (a coil-shaped carbon nanotube forming a spiral when viewed in entirety), a carbon nanobead (a spherical bead made of amorphous carbon or the like with its center pierced by a tube), a cup-stacked nanotube, and a carbon nanotube with its circumference covered with a carbon nanohorn or amorphous carbon.

Furthermore, carbon nanotubes in the present invention may be ones that contain some substance inside, such as a metal-containing nanotube which is a carbon nanotube containing metal or the like, and a peapod nanotube which is a carbon nanotube containing a fullerene or a metal-containing fullerene.

As described above, the present invention can employ carbon nanotubes of any mode, including common carbon nanotubes, variants of common carbon nanotubes, and carbon nanotubes with various modifications, without a problem in terms of reactivity. Therefore, the concept of carbon nanotube in the present invention encompasses all of the above.

Those carbon nanotubes are conventionally synthesized by a known method, such as arc discharge, laser ablation, and CVD, and the present invention can employ any of the methods. However, arc discharge in a magnetic field is preferable from the viewpoint of synthesizing a highly pure carbon nanotube.

Carbon nanotubes used in the present invention are preferably equal to and more than 0.3 nm and equal to or less than 100 nm in diameter. If the diameter of the carbon nanotubes exceeds this upper limit, the synthesis becomes difficult and costly. A more desirable upper limit of the diameter of the carbon nanotubes is 30 nm or less.

In general, the lower limit of carbon nanotube diameter is about 0.3 nm from a structural standpoint. However, too thin a diameter could lower the synthesis yield. It is therefore desirable to set the lower limit of carbon nanotube diameter to 1 nm or more, more desirably 10 nm or more.

The length of carbon nanotubes used in the present invention is preferably equal to or more than 0.1 μm and equal to or less than 100 μm. If the length of the carbon nanotubes exceeds this upper limit, the synthesis becomes difficult or requires a special method raising cost. On the other hand, if the length of the carbon nanotubes falls short of this lower limit, the number of cross-link bonding points per carbon nanotube is reduced, which is undesirable. A more desirable upper limit of carbon nanotube length is 10 μm or less and a more desirable lower limit of carbon nanotube length is 1 μm or more.

The appropriate carbon nanotube content in the cross-linking application liquid is varied depending on the length and thickness of carbon nanotubes, whether single-wall carbon nanotubes or multi-wall carbon nanotubes are used, the type and amount of functional groups in the carbon nanotubes, the type and amount of cross-linking agents or an additive for bonding functional groups together, whether there is a solvent or other additive used and, if one is used, the type and amount of the solvent or additive, etc. The carbon nanotube concentration in the liquid solution should be high enough to form an excellent coat by application and curing but not too high to make it difficult to apply the liquid.

Specifically, the ratio of carbon nanotubes to the entire application liquid excluding the mass of the functional groups is 0.01 to 10 g/l, desirably 0.1 to 5 g/l, and more desirably 0.5 to 1.5 g/l, although, as mentioned above, the ranges could be different if the parameters are different.

If the purity of carbon nanotubes to be used is not high enough, it is desirable to raise the purity by refining the carbon nanotubes prior to preparation of the cross-linking application liquid. In the present invention, the higher the carbon nanotube purity, the better the result can be. Specifically, the purity is desirably 90% or higher, more desirably, 95% or higher. When the purity is low, cross-linking agents are cross-linked to carbon products such as amorphous carbon and tar, which are impurities. This could change the cross-linking distance between carbon nanotubes, leading to a failure in obtaining desired characteristics. No particular limitation is put on how carbon nanotubes are refined, and any known refining method can be employed.

(Functional Group 1)

In the first method in which the cross-linked site is formed using a cross-linking agent, carbon nanotubes can have any functional group to be connected thereto, as long as-functional groups chosen can be added to the carbon nanotubes chemically and can prompt a cross-linking reaction with any kind of cross-linking agent. Specific examples of such functional groups include —COOR, —COX, —MgX, —X (X represents halogen), —OR, —NR¹R², —NCO, —NCS, —COOH, —OH, —NH₂, —SH, —SO₃H, —R′CHOH, —CHO, —CN, —COSH, —SR, —SiR′₃ (R, R¹, R², and R′ each represent a substituted or unsubstituted hydrocarbon group). Note that employable functional groups are not limited to those examples.

Of those, a selection of one functional group selected from the group consisting of —OH, —COOH, —COOR (R is a substituted or unsubstituted hydrocarbon group), —COX (X is a halogen atom), —NH₂, and —NCO is preferable. In that case, a cross-linking agent, which can prompt a cross-linking reaction with the selected functional group, is selected as the cross-linking agent.

In particular, —COOR (where R represents a substituted or unsubstituted hydrocarbon group) is particularly preferable. This is because a carboxyl group can be relatively easily introduced into a carbon nanotube, because the resultant substance (a carbon nanotube carboxylic acid) can be easily introduced as a functional group by esterifying the substance, and because the substance has good reactivity with a crosslinking agent.

R in the functional group —COOR is a substituted or unsubstituted hydrocarbon group, and is not particularly limited. However, R is preferably an alkyl group having 1 to 10 carbon atoms, more preferably an alkyl group having 1 to 5 carbon atoms, and particularly preferably a methyl group or an ethyl group in terms of reactivity, solubility, viscosity, and ease of use as a solvent of a paint.

The appropriate amount of functional groups introduced varies depending on the length and thickness of carbon nanotubes, whether single-wall carbon nanotubes or multi-wall carbon nanotubes are used, the type of functional groups, the use of a wire obtained, etc. From the viewpoint of the strength of the cross-linked body obtained, namely, the strength of the coat formed by application, a preferable amount of functional groups introduced is large enough to add two or more functional groups to each carbon nanotube. How functional groups are introduced into carbon nanotubes will be explained in a section below titled [Method of Manufacturing a Wire].

(Cross-Linking Agent)

Any cross-linking agent, which is an essential ingredient of the cross-linking application liquid, that is capable of prompting a cross-linking reaction with the functional groups of the carbon nanotubes can be used. In other words, the types of cross-linking agents that can be chosen are limited to a certain degree by the types of the functional groups. Also, the conditions of curing (heating, UV irradiation, irradiation of visible light, natural curing, etc.) as a result of the cross-linking reaction are naturally determined by the combination of those parameters.

Specific examples of the preferable cross-linking agents include polyol, polyamine, polycarboxylic acid, polycarboxylate, polycarboxylic acid halide, polycarbodiimide, and polyisocyanate. It is desirable to choose at least one cross-lining agent from the group consisting of the above. In that case, a functional group which can prompt a reaction with the cross-linking agent is selected as the functional group.

At least one functional group and one cross-linking agent are particularly preferably selected respectively from the group exemplified as the preferable functional group and the group exemplified as the preferable cross-linking agent, so that a combination thereof may prompt a cross-linking reaction with one another. The following Table 1 lists the combinations of the functional group of the carbon nanotubes and the corresponding cross-linking agent, which can prompt a cross-linking reaction, along with curing conditions of the combinations.

TABLE 1

| Functional groups of | | |
|---|---|---|
| carbon nanotubes | Cross-linking agent | Curing condition |
| —COOR | polyol | heat curing |
| —COX | polyol | heat curing |
| —COOH | polyamine | heat curing |
| —COX | polyamine | heat curing |
| —OH | polycarboxylate | heat curing |
| —OH | polycarboxylic acid halide | heat curing |
| —NH₂ | polycarboxylic acid | heat curing |
| —NH₂ | polycarboxylic acid halide | heat curing |
| —COOH | polycarbodiimide | heat curing |
| —OH | polycarbodiimide | heat curing |
| —NH₂ | polycarbodiimide | heat curing |
| —NCO | polyol | heat curing |
| —OH | polyisocyanate | heat curing |
| —COOH | ammonium complex | heat curing |
| —COOH | Cisplatin | heat curing |

*R is a substituted or unsubstituted hydrocarbon group
*X is a halogen

Out of those combinations, preferable is the combination of —COOR (where R represents a substituted or unsubstituted hydrocarbon group) with good reactivity on a functional group side and a polyol that forms a robust cross-linked substance with ease. The term “polyol” in the present invention is a genetic name for organic compounds each having two or more OH groups. Of those, a polyol having 2 to 10 (more preferably 2 to 5) carbon atoms and 2 to 22 (more preferably 2 to 5) OH groups is preferable in terms of cross-linkability, solvent compatibility when an excessive amount of the polyol is charged, processability of liquid waste after a reaction by virtue of biodegradability (environment aptitude), yield of polyol synthesis, and so on. In particular, the number of carbon atoms is preferably lower within the above range because a space between carbon nanotubes in a coat to be obtained can be narrowed to bring the carbon nanotubes into substantial contact with each other (to bring the carbon nanotubes close to each other). Specifically, glycerin and ethylene glycol are particularly preferable, and it is preferable to use one or both of glycerin and ethylene glycol as a crosslinking agent.

From another perspective, the cross-linking agent is preferably a not self-polymerizable cross-linking agent. Examples of the polyols such as glycerin and ethylene glycol are not self-polymerizable cross-linking agents. More generally, a prerequisite of the not self-polymerizable cross-linking agent is to be without a pair of functional groups, which can prompt a polymerization reaction to one another, in itself. On the other hand, examples of a self-polymerizable cross-linking agent include one that has a pair of functional groups, which can prompt a polymerization reaction with one another (alkoxide, for example).

(Functional Group 2)

Further, in the second method of obtaining a mesh structure of mutually cross-linked carbon nanotubes, a cross-linked site of the carbon nanotube structure is formed by chemically bonding plural functional groups, in which at least one end of the cross-linked site is bonded to different carbon nanotubes respectively. In the second method, the functional group to be bonded to the carbon nanotubes can be chemically added to the carbon nanotubes. In addition, as long as being capable of reacting to one another with any kind of additive, the functional group is not particularly limited, and any functional group can be selected. Specific examples of the functional group include —COOR, —COX, —MgX—, —X (X is a halogen), —OR, —NR¹R², —NCO, —NCS, —COOH, —OH, —NH₂, —SH, —SO₃H, —R′CHOH, —CHO, —CN, —COSH, —SR, —SiR′₃ (each of R, R¹, R², and R³ independently is a substituted or unsubstituted hydrocarbon group), but are not limited to those.

Of those, the preferable functional group includes: at least one functional group selected from the group consisting of —COOR (R is a substituted or unsubstituted hydrocarbon group), —COOH, —COX (X is a halogen atom), —OH, —CHO—, and —NH₂ for the condensation reaction; at least one functional group selected from the group consisting of —NH₂, —X (X is a halogen atom), —SH, —OH, —OSO₂CH₃, and —OSO₂(C₆H₄)CH₃ for the substitution reaction; at least one functional group selected from the group consisting of —OH and —NCO for the addition reaction; and —SH for the oxidative reaction.

Further, bonding a molecule, which partially contains those functional groups, with the carbon nanotubes to be chemically bonded at a preferable functional group portion exemplified above is also possible. Even in this case, a functional group with large molecular weight to be bonded to the carbon nanotubes is bonded as intended, enabling a control of a length of the cross-linked site.

(Additive)

Any additive that is capable of making the functional groups of the carbon nanotubes react to one another can be mixed in the cross-linking application liquid. In other words, the types of additives that can be chosen are limited to a certain degree by the types of the functional groups and the reaction type. Also, the condition of curing (heating, UV irradiation, irradiation of visible light, natural curing, etc.) as a result of the reaction is naturally determined by the combination of those parameters.

(Condensing Agent)

To give specific examples of preferable additives, an acid catalyst or a dehydration condensation agent, for example, sulfuric acid, N-ethyl-N′-(3-dimethylaminopropyl)carbodiimide, and dicyclohexyl carbodiimide, is preferred as a condensing agent. Desirably, at least one condensing agent is chosen from the group consisting of the above. The functional groups chosen have to react to one another with the help of the selected condensing agent.

(Base)

When a substitution reaction is to be utilized, a base is an indispensable component of the cross-linking application liquid. An arbitrary base is chosen in accordance with the degree of acidity of hydroxyl groups.

Preferably, the base is at least one chosen from the group consisting of sodium hydroxide, potassium hydroxide, pyridine, and sodium ethoxide. A substitution reaction is to take place among the functional groups with the help of the selected base.

It is particularly desirable to select a combination of functional groups such that at least two functional groups from each of the example groups that are given above as examples of preferable functional groups react to each other. Listed in Table 2 below are functional groups of carbon nanotubes and names of the corresponding reactions.

An addition reaction does not necessarily need an additive. In an oxidative reaction, an additive is not necessarily needed but adding an oxidative reaction accelerator is preferable. A specific example of the accelerator is iodine.

TABLE 2

| | Functional group | Functional group | |
|---|---|---|---|
| | of carbon | of carbon | |
| Bonding site | nanotubes(A) | nanotubes (B) | Reaction |
| —COOCO— | —COOH | — | Dehydration |
| | | | condensation |
| —S—S— | —SH | — | Oxidative |
| | | | reaction |
| —O— | —OH | — | Dehydration |
| | | | condensation |
| —NH—CO— | —COOH | —NH₂ | Dehydration |
| | | condensation | |
| —COO— | —COOH | —OH | Dehydration |
| | | | condensation |
| —COO— | —COOR | —OH | Dehydration |
| | | | condensation |
| —COO— | —COX | —OH | Dehydration |
| | | | condensation |
| —CH═N— | —CHO | —NH₂ | Dehydration |
| | | | condensation |
| —NH— | —NH₂ | —X | Substitution |
| | | | reaction |
| —S— | —SH | —X | Substitution |
| | | | reaction |
| —O— | —OH | —X | Substitution |
| | | | reaction |
| —O— | —OH | —OSO₂CH₃ | Substitution |
| | | | reaction |
| —O— | —OH | —OSO₂(C₆H₄)CH₃ | Substitution |
| | | | reaction |
| —NH—COO— | —OH | —N═C═O | Addition |
| | | | reaction |

*R is a substituted or unsubstituted hydrocarbon group
*X is a halogen

Of course, the content of a crosslinking agent or of an additive for bonding a functional group in the cross-linking application liquid varies depending on the type of the crosslinking agent (including whether the crosslinking agent is self-polymerizable or not self-polymerizable) and the type of the additive for bonding a functional group. The content also varies depending on the length and thickness of a carbon nanotube, whether the carbon nanotube is of a single-wall type or a multi-wall type, the kind and amount of a functional group of the carbon nanotube, the presence or absence, kinds, and amounts of a solvent and other additives, and the like. Therefore, the content can not be determined uniquely. In particular, for example, glycerin or ethylene glycol can also provide characteristics of a solvent because a viscosity of glycerin or ethylene glycol is not so high, and thus an excessive amount of glycerin or ethylene glycol can be added.

(Other Additive)

The cross-linking application liquid may contain various additives including a solvent, a viscosity adjuster, a dispersant, and a cross-linking accelerator. A solvent is added when satisfactory application of the cross-linking application liquid is not achieved with solely the cross-linking agents or the additive for bonding the functional groups. Any solvent can be appropriately employed without particular limitation as long as it is suitable for the cross-linking agents. Specific examples of employable solvents include: organic solvents such as methanol, ethanol, isopropanol, n-propanol, butanol, methyl ethyl ketone, toluene, benzene, acetone, chloroform, methylene chloride, acetonitrile, diethyl ether, tetrahydrofuran (THF); water; aqueous solutions of acids; and alkaline aqueous solutions. A solvent as such is added in an amount that is not particularly limited but determined appropriately by taking into consideration the ease of applying the cross-linking application liquid.

A viscosity adjuster is added when satisfactory application of the cross-linking application liquid is not achieved with solely the cross-linking agents and the additive for bonding the functional groups. Any viscosity adjuster can be appropriately employed without any limitation as long as it is suitable for the cross-linking agents and the additive for bonding and the functional groups used. Specific examples of employable viscosity adjusters include methanol, ethanol, isopropanol, n-propanol, butanol, methyl ethyl ketone, toluene, benzene, acetone, chloroform, methylene chloride, acetonitrile, diethyl ether, and THF.

Some of those viscosity adjusters obtain the function of a solvent when added in a certain amount, and it is meaningless to apparently discriminate viscosity adjusters from solvents. A viscosity adjuster as such is added in an amount that is not particularly limited but determined by taking into consideration the ease of applying the cross-linking application liquid.

A dispersant is added to the cross-linking application liquid in order to maintain the dispersion stability of the carbon nanotubes or the cross-linking agents or the additive for bonding and the functional groups in the application liquid. Various known surface-active agents, water-soluble organic solvents, water, aqueous solutions of acids, alkaline aqueous solutions, etc. can be employed as a dispersant. However, a dispersant is not always necessary since components of the coating material (cross-linking application liquid) of the present invention have high dispersion stability by themselves. In addition, depending on the use of the coat formed by applying the cross-linking application liquid, the presence of a dispersant and like other impurities in the coat may not be desirable. In such case, a dispersant is not added at all, or is added in a very small amount.

(Method of Preparing the Cross-linking Application Liquid)

A method of preparing the cross-linking application liquid is described next. The cross-linking application liquid is prepared by mixing, as needed, carbon nanotubes that have functional groups with a cross-linking agent that prompts a cross-linking reaction with the functional groups or an additive that causes the functional groups to form chemical bonds among themselves (mixing step). The mixing step may be preceded by an addition step in which the functional groups are introduced into the carbon nanotubes.

If carbon nanotubes having functional groups are starting material, the preparation starts with the mixing step. If normal carbon nanotubes themselves are starting material, the preparation starts with the addition step. The addition step is a step for introducing desired functional groups into carbon nanotubes. How functional groups are introduced is varied depending on the type of functional group. One method is to add a desired functional group directly, and another method is to introduce a functional group that is easy to attach and then substitute the whole functional group or a part thereof or attach a different functional group to the former functional group in order to obtain the objective functional group. Still another method is to apply a mechanochemical force to a carbon nanotube to break or alter only a small portion of a graphene sheet on the surface of the carbon nanotube and introduce various functional groups from the broken or altered portion.

Cup-stacked carbon nanotubes, which have many defects on the surface upon manufacture, and carbon nanotubes that are formed by vapor phase growth are relatively easy to introduce functional groups. On the other hand, carbon nanotubes that have a perfect graphene sheet structure exert the carbon nanotube characteristics more effectively and are easier to control the characteristics. Consequently, it is particularly desirable to use a multi-wall carbon nanotube so that defects formed as many as appropriate as a wire on its outermost layer are used to bond functional groups for cross-linking while the inner layers having less structural defects exert the carbon nanotube characteristics.

There is no particular limitation put on the addition step and any known method can be employed. Various addition methods disclosed in JP 2002-503204 A may be employed in the present invention depending on the purpose. A description is given on a method of introducing —COOR (R is a substituted or unsubstituted hydrocarbon group), a particularly desirable functional group among the functional groups listed in the above. To introduce —COOR (R is a substituted or unsubstituted hydrocarbon group) into carbon nanotubes, carboxyl groups may be (1) added to the carbon nanotubes once, and then (2) esterified.

(1) Addition of Carboxyl Group

To introduce carboxyl groups into carbon nanotubes, carboxyl groups are refluxed together with an acid having an oxidizing effect. This operation is relatively easy and is preferable since carboxyl groups which are rich in reactivity are attached to carbon nanotubes. A brief description of the operation is given below.

An acid having an-oxidizing effect is, for example, concentrated nitric acid, hydrogen peroxide water, a mixture of sulfuric acid and nitric acid, or aqua regia. When concentrated nitric acid is used, in particular, the concentration is desirably 5 mass % or higher, more desirably, 60 mass % or higher.

A normal reflux method can be employed. The temperature is preferably set to a level near the boiling point of the acid used. When concentrated nitric acid is used, for instance, the temperature is preferably set to 120 to 130° C. The reflux desirably lasts 30 minutes to 20 hours, more desirably, 1 hour to 8 hours.

Carbon nanotubes to which carboxyl groups are attached (carbon nanotube carboxylic acid) are generated in the reaction liquid after the reflux. The reaction liquid is cooled down to room temperature and then receives a separation operation or washing as necessary, thereby obtaining the objective carbon nanotube carboxylic acid.

(2) Esterification

The target functional group —COOR (R is a substituted or unsubstituted hydrocarbon group) can be introduced by adding an alcohol to the obtained carbon nanotube carboxylic acid and dehydrating for esterification.

The alcohol used for the esterification is determined according to R in the formula of the functional group. That is, if R is CH₃, alcohol is methanol, and if R is C₂H₅, alcohol is ethanol. A catalyst is generally used in the esterification, and a conventionally known catalyst such as sulfuric acid, hydrochloric acid, and toluenesulfonic acid can also be used in the present invention. A use of the sulfuric acid as a catalyst is preferable from a view of not prompting a side reaction in the present invention.

The esterification may be conducted by adding an alcohol and a catalyst to carbon nanotube carboxylic acid and refluxing at an appropriate temperature for an appropriate time period. A temperature condition and a time period condition depend on type of a catalyst, type of alcohol, or the like and cannot be simply determined, but a reflux temperature close to a boiling point of the alcohol used is preferable. A range of 60 to 70° C. is preferable for methanol, for example. Further, a time period is preferably in a range of 1 to 20 hours, more preferably in a range of 4 to 6 hours.

Carbon nanotubes with the functional group —COOR (R is a substituted or unsubstituted hydrocarbon group) added can be obtained by separating a reaction product from a reaction solution after esterification and washing as required.

The mixing step is a step of mixing, as required, a cross-linking agent prompting a cross-linking reaction with the functional groups or an additive for bonding the functional groups with the carbon nanotubes which contain functional groups to prepare the cross-linking application liquid. In the mixing step, other components described in the aforementioned section titled [Wire] are added, in addition to the carbon nanotubes containing functional groups and the cross-linking agents. Then, preferably, an amount of a solvent or a viscosity control agent is adjusted considering applicability to prepare the cross-linking application liquid just before application.

A simple stirring with a spatula and stirring with an agitator of an agitating blade type, a magnetic stirrer, and a stirring pump may be used. However, to achieve higher degree of uniformity in dispersion of the carbon nanotubes to enhance storage stability while fully extending a mesh structure by cross-linking of the carbon nanotubes, an ultrasonic disperser or a homogenizer may be used for powerful dispersion. However, when using a stirring device with a strong shear force of stirring, there arises a risk of cutting and damaging the carbon nanotubes contained, thus the device may be used for a very short time period.

A carbon nanotube structure is formed by applying the cross-linking application liquid described above to a base body surface and curing. An applying method and a curing method are described in detail in a section below titled [Method of Manufacturing a Wire] described later.

The carbon nanotube structure layer in the present invention is in a state where carbon nanotubes are networked. In detail, the carbon nanotube structure is cured into a matrix shape, carbon nanotubes are connected to each other via cross-linked sites, and characteristics of a carbon nanotube itself such as high electron- and hole-transmission characteristics can be exerted sufficiently. In other words, the carbon nanotube structure has carbon nanotubes that are tightly connected to each other, contains no other binders and the like, and is thus substantially composed only of carbon nanotubes, so that intrinsic characteristics of a carbon nanotube are fully utilized.

A thickness of the carbon nanotube structure of the present invention can be widely selected from being very thin to being thick according to an application. Lowering a content of the carbon nanotubes in the cross-linking application liquid used (simply, lowering the viscosity by diluting) and applying in a thin coat form allows a very thin coat to be obtained. Similarly, raising a content of the carbon nanotubes allows a thick coat to be obtained. Further, repeating the application allows an even thicker coat to be obtained. Formation of a very thin coat from a thickness of about 10 nm is possible, and formation of a thick coat without an upper limit is possible through recoating. A possible coat thickness with one coating is about 5 μm. Further, a desired shape of the structure can be obtained by injecting the cross-linking application liquid, in which a content or the like is adjusted, to a mold and bonding.

In the carbon nanotube structure, when using the cross-linking agent of the first method, a site where the carbon nanotubes cross-link together, that is, the cross-linked site formed by a cross-linking reaction between the functional groups of the carbon nanotubes and the cross-linking agents has a cross-linking structure. In the cross-linking structure, residues of the functional group remaining after a cross-linking reaction are connected together with a connecting group, which is a residue of the cross-linking agent remaining after a cross-linking reaction.

As described, the cross-linking agent, which is a component of the cross-linking application liquid, is preferably not self-polymerizable. If the cross-linking agent is not self-polymerizable, the carbon nanotube structure layer finally manufactured would be configured from a residue of only one cross-linking agent. The gap between the carbon nanotubes to be cross-linked can be controlled to a size of a residue of the cross-linking agent, thereby providing a desired network structure of the carbon nanotubes with high duplicability. Further, multiple cross-linking agents are not present between the carbon nanotubes, thus enabling an enhancement of a substantial density of the carbon nanotubes in the carbon nanotube structure. Further, by reducing a size of a residue of the cross-linking agent, a gap between each of the carbon nanotubes can be configured in an extremely close state electrically and physically (carbon nanotubes are substantially in direct contact with each other).

When forming the carbon nanotube structure with a cross-linking application liquid prepared by selecting a single functional group of the carbon nanotubes and a single not-self-polymerizable cross-linking agent, the cross-linked site of the layer will have the same cross-linking structure (Example 1). Further, even when forming the carbon nanotube structure layer with a cross-linking application liquid prepared by selecting multiple types of functional groups of the carbon nanotubes and/or multiple types of not-self-polymerizable cross-linking agents, the cross-linked site of the layer will mainly have a cross-linking structure based on a combination of the functional group and the not self-polymerizable cross-linking agent mainly used (Example 2).

On the contrary, when forming the carbon nanotube structure layer with a cross-linking application liquid prepared by selecting self-polymerizable cross-linking agents, without regard to whether the functional groups and the cross-linking agents are of single or multiple types, the cross-linked site of the layer will not mainly have a specific cross-linking structure. The cross-linked site will be in a state in which numerous connecting groups with different connecting (polymerization) numbers of the cross-linking agents coexist.

In other words, by selecting not self-polymerizable cross-linking agents, the cross-linked sites, where the carbon nanotubes of the carbon nanotube structure layer cross-link together, bond with the functional group through a residue of only one cross-linking agent, thus forming mainly identical cross-linking structure. “Mainly identical” here is a concept including a case with all of the cross-linked sites having identical cross-linking structure as described above (Example 1), as well as a case with the cross-linking structure based on a combination of the functional group mainly used and the not self-polymerizable cross-linking agent becomes a main structure with respect to the whole cross-linked site as described above (Example 2).

A “ratio of identical cross-linked sites” with respect to the whole cross-linked sites will not have a uniform lower limit defined. The reason is that a case of imparting a functional group or a cross-linking structure with a different aim from formation of a carbon nanotube network may be assumed for example, when referring as “mainly identical”. However, in order to actualize high electrical or physical characteristics inherent in carbon nanotubes with a strong network, a “ratio of identical cross-linked sites” with respect to the total cross-linked sites is preferably 50% or more, more preferably 70% or more, further more preferably 90% or more, and most preferably all identical, based on numbers. Those number ratios can be determined through a method of measuring an intensity ratio of an absorption spectrum corresponding to the cross-linking structure with infrared spectrum or the like.

As described, if a carbon nanotube structure layer has the cross-linked site where carbon nanotubes cross-link with a mainly identical cross-linking structure, a uniform network of the carbon nanotubes can be formed in a desired state. In addition, the carbon nanotube network can be configured with homogeneous, satisfactory, and expected electrical or physical characteristics and high duplicability.

Further, the connecting group preferably contains hydrocarbon for a skeleton thereof. “Hydrocarbon for a skeleton” here refers to a main chain portion of the connecting group consisting of hydrocarbon, the main portion of the connecting group contributing to connecting residues together of the functional groups of carbon nanotubes to be cross-linked remaining after a cross-linking reaction. A side chain portion, where hydrogen of the main chain portion is substituted by another substituent, is not considered. Obviously, it is more preferable that the whole connecting group consists of hydrocarbon.

A number of carbon atoms in the hydrocarbon is preferably 2 to 10, more preferably 2 to 5, and further more preferably 2 to 3. The connecting group is not particularly limited as long as it is divalent or more.

In the cross-linking reaction of the functional group —COOR (R is a substituted or unsubstituted hydrocarbon) and ethylene glycol, exemplified as a preferable combination of the functional group of carbon nanotubes and the cross-linking agent, the cross-linked site, where plural carbon nanotubes cross-link to one another, becomes —COO(CH₂)₂OCO—.

Further, in the cross-linking reaction of the functional group —COOR (R is a substituted or unsubstituted hydrocarbon) and glycerin, the cross-linked site, where plural carbon nanotubes cross-link to one another, becomes —COOCH₂CHOHCH₂OCO— or —COOCH₂CH(OCO—)CH₂OH if two OH groups contribute in the cross-link, and —COOCH₂CH(OCO—)CH₂—CO— if three OH groups contribute in the cross-link.

As has been described, in a wire of the present invention, a carbon nanotube structure layer has a mesh structure that is composed of plural carbon nanotubes connected to one another through plural cross-linked sites. Thus, contact or arrangement of carbon nanotubes is not disturbed, unlike a mere carbon nanotube dispersion film. Therefore, there are stably obtained characteristics that are unique of carbon nanotubes, including: electrical characteristics such as high transmission characteristics of electrons and holes; physical characteristics such as thermal conductivity and toughness; and light absorption characteristics.

Further, in the second method forming the cross-linked site through chemically bonding plural functional groups, in which at least one end of the cross-linked site is bonded to different carbon nanotubes respectively, the carbon nanotube structure has carbon nanotubes connected through a cross-linked portion in a matrix form. Therefore, characteristics that carbon nanotubes have, such as high transmission characteristics of electrons and holes, are easily obtained. That is, in the carbon nanotube structure, carbon nanotubes are tightly connected together, and other binders are not contained. Therefore, the carbon nanotube structure can be substantially configured only with carbon nanotubes.

Further, the cross-linked sites are formed by a reaction among the functional groups, thus enabling an enhancement of the actual carbon nanotube density of the carbon nanotube structure. If the functional groups are reduced in size, the carbon nanotubes can be brought very close to one another both electrically and physically, and characteristics of a carbon nanotube itself can be easily obtained.

Further, cross-linked sites are chemical bonds of the functional groups, thus the carbon nanotube structures mainly have the same cross-linking structure. Therefore, a uniform network of carbon nanotubes can be brought into a desired state. Therefore, electric and physical carbon nanotube characteristics that are homogeneous and excellent can be obtained. Furthermore, electrical or physical characteristics can be made the exact characteristics expected from carbon nanotubes, or close to the expected level or with high duplicability, can be obtained.

A layer except the carbon nanotube structure layer to be used as a lead wire may be formed in the wire of the present invention. For example, placing an adhesive layer between the surface of the substrate and the carbon nanotube structure layer for enhancing adhesiveness therebetween can improve the adhesive strength of a patterned carbon nanotube structure layer, and is thus preferable. In addition, the periphery of the carbon nanotube structure can be coated with an insulator, an electric conductor, or the like according to wire applications.

As already mentioned, the base body may be a substrate that has plasticity or flexibility. With a plastic or flexible substrate serving as the base body, the entire wire is improved in flexibility, and options of places to install the carbon nanotube structure (environments in which the carbon nanotube structure can be used) are increased greatly.

In addition, when constituting a device, a wire that uses a plastic or flexible substrate can be adapted to various arrangements in the device and can take various shapes, and is thus essential for functioning as a coil.

Specifics of the above-described wire of the present invention including its shape and the like will be made clear in the following section of [Method of Manufacturing a Wire] and Example. Note that the descriptions below show merely examples and are not to limit specific modes of the wire of the present invention.

[Method of Manufacturing a Wire]

A wire manufacturing method of the present invention is a method suitable for manufacture of the above-described wire of the present invention. Specifically, the wire manufacturing method of the present invention includes (A) an applying step for applying a surface of a base body with a liquid solution that contains plural carbon nanotubes having functional groups connected thereto, and (B) a cross-linking step for forming a carbon nanotube structure layer that has a mesh structure composed of the plural carbon nanotubes that are cross-linked to one another by chemical bonds formed among the functional groups.

Hereinafter, an example of a method of manufacturing a wire according to the present invention will be described for each step with reference to FIG. 2.

(A) Applying Step

In the present invention, the “applying step” is a step of applying to the surface of the substrate 2 a liquid solution containing a carbon nanotube having a functional group (a cross-linking application liquid 11). An application unit 4 stores the cross-linking application liquid 11 in its container, conveys the cross-linking application liquid 11 via the surface of a roller 41 rotating in the unit, and applies the cross-linking application liquid in a linear shape to the substrate 2.

Any method can be applied to supply the cross-linking application liquid, and the liquid may be simply dropped or spread with a squeegee or may be applied by a common application method. Examples of common application methods include spin coating, wire bar coating, cast coating, roll coating, brush coating, dip coating, spray coating, and curtain coating.

(B) Cross-Linking Step

In the present invention, the “cross-linking step” is a step of curing the cross-linking application liquid 11 after the application to form the carbon nanotube structure 1 in which the plural carbon nanotubes mutually cross-link to configure a mesh structure. A cross-linking reaction unit 5 includes a heater or an ultraviolet light source 51, and irradiates the cross-linking application liquid 11 applied to the substrate 2 with ultraviolet light. A carbon nanotube reacts at its functional group site to form a cross-linked site.

What operation should be carried out in the cross-linking step is naturally determined by the combination of the functional groups with the cross-linking agent or the additive for chemically bonding the functional groups together. If a combination of thermally curable functional groups is employed, the applied liquid is heated by a heater or the like. If a combination of functional groups that are cured by ultraviolet rays is employed, the applied liquid is irradiated with a UV lamp or left under the sun. If a combination of self-curable functional groups is employed, it is sufficient to let the applied liquid stand still. Leaving the applied liquid to stand still is deemed as one of the operations that may be carried out in the cross-linking step of the present invention.

Heat curing (polyesterification through ester exchange reaction) is conducted for the case of a combination of carbon nanotubes, to which the functional group —COOR (R is a substituted or unsubstituted hydrocarbon group) is added, and polyol (among them, glycerin and/or ethylene glycol). By heating, —COOR of the esterified carbon nanotube carboxylic acid and R′—OH (R′ is a substituted or unsubstituted hydrocarbon group) of polyol react in ester exchange reaction. As the dehydration condensation reaction progresses multilaterally, the carbon nanotubes are cross-linked until a network of carbon nanotubes connected to one another constitutes a carbon nanotube structure layer 14.

To give an example of conditions preferable for the above combination, specifically, the heating temperature is set to 50 to 500° C., more desirably 150 to 200° C., and the heating period is set to 1 minute to 10 hours, more desirably 1 hour to 2 hours.

Next, a step of coating a carbon nanotube structure may be arbitrarily included. The carbon nanotube structure 1 after the cross-linking is conveyed by virtue of the rotation of a winding unit (not shown) on the substrate 2 to reach a coating application unit 6. An insulating resin 30 that is heated by a not-shown heater and is in a fused state is stored in a container of the application unit, and is applied to the carbon nanotube structure in accordance with the rotation of a roller 61. After the resin 30 has been cooled, the coating 3 cures.

Note that the above procedure is merely one example, and if a protective layer, an electrode layer, and other such layers are to be individually layered, appropriate materials and methods are chosen by known materials and methods, or materials and methods developed specially for the present invention are used, to form those layers.

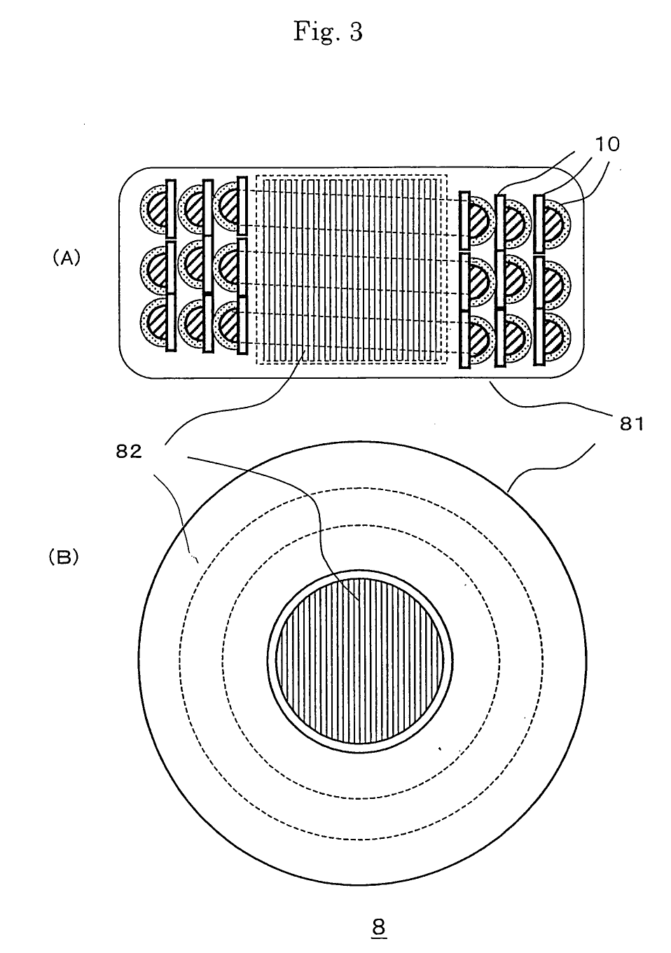

Next, an electromagnet as an application example using the wire of the present invention is described with reference to FIG. 3.

FIG. 3(A) is a side view of an electromagnet 8 of this embodiment, and FIG. 3(B) is a top view thereof.

The electromagnet 8 is formed by arranging an iron core 82 made of a magnetic material at a center and by winding the wire 10 around the core by multiple times, and is protected by a case 81. The electromagnet 8 is formed by the wire 10 constituted by the carbon nanotube structure 1 in which carbon nanotubes mutually cross-link to configure a mesh structure, so that breakage of bonding between nanotubes does not take place upon winding and the electromagnet can be flexibly used as a lead wire.

Furthermore, a carbon nanotube itself has a resistivity lower than that of copper, and is free of a critical current that has been a critical defect in a superconductor. Moreover, a specific gravity of a carbon nanotube is about 1, which means that the carbon nanotube is extremely lightweight. Therefore, the construction of an electromagnet using a structure, which is configured by bonding carbon nanotubes, as a wire forms an electromagnet, scarcely causing a loss of heat or the like because the main portion of the structure is configured by carbon nanotubes. It is preferable that an electric conductivity of a wire to be used be as low as possible because the electric conductivity varies depending on the chemical structure of a cross-linked site. Particularly preferable is a structure containing a carbon-carbon double bond in which the structure of a cross-linked site is close to the graphite structure and in which a conduction band of π-electron is formed over the whole cross-linked site between carbon nanotubes.

A more specific description of the present invention is given below through Examples. However, the present invention is not limited to the following examples.

### EXAMPLE 1

A wire was manufactured through a flow of a manufacturing method for a wire shown in FIG. 1. It should be noted that reference numerals in FIG. 1 may be used in the description of this example.

(A) Applying Step

(A-1) Preparation of Cross-Linking Application Liquid (Addition Step)

(1) Addition of Carboxyl Group . . . Synthesis of Carbon Nanotube Carboxylic Acid

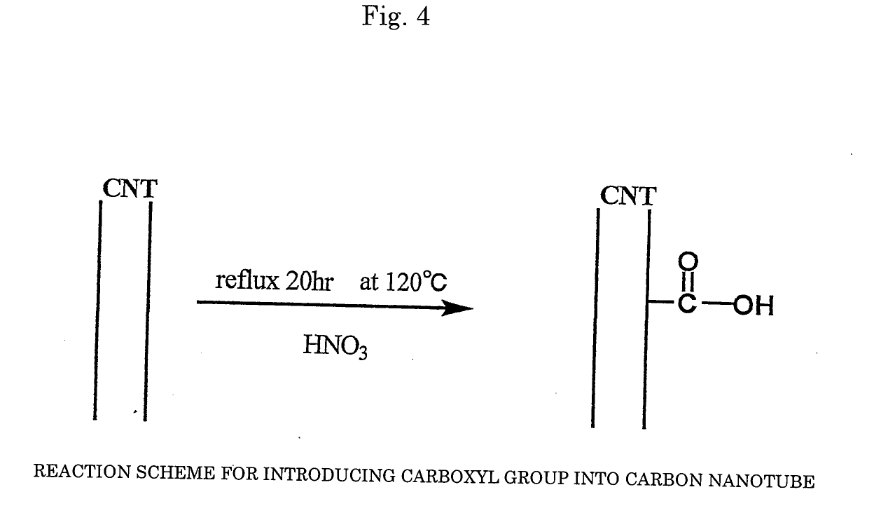

30 mg of multi-layer carbon nanotube powder (purity: 90%, average diameter: 30 nm, average length: 3 μm, available from Science Laboratory Inc.) was added to 20 ml of concentrated nitric acid (a 60 mass % aqueous solution, available from KANTO KAGAKU) for reflux at 120° C. for 20 hours to synthesize carbon nanotube carboxylic acid. A reaction scheme of the above is shown in FIG. 4. In FIG. 4, a carbon nanotube (CNT) is represented by two parallel lines (same applies for other figures relating to reaction scheme).

The temperature of the liquid solution was returned to room temperature and centrifuged at 5,000 rpm for 15 minutes to separate supernatant liquid from precipitate. The recovered precipitate was dispersed in 10 ml of pure water, and the dispersion liquid was subjected to centrifugal separation again at 5,000 rpm for 15 minutes to separate supernatant liquid from precipitate (the above process constitutes one washing operation). This washing operation was repeated five more times and lastly precipitate was recovered.

An infrared absorption spectrum of the recovered precipitate was measured. An infrared absorption spectrum of the used multi-wall carbon nanotube raw material itself was also measured for comparison. A comparison between both the spectra revealed that absorption at 1735 cm⁻¹ characteristic of a carboxylic acid, which was not observed in the multi-wall carbon nanotube raw material itself, was observed in the precipitate. This finding shows that a carboxyl group was introduced into a carbon nanotube by the reaction with nitric acid. In other words, this finding confirmed that the precipitate was a carbon nanotube carboxylic acid.

Addition of neutral pure water to the recovered precipitate confirmed that dispensability was good. This result supports the result of the infrared absorption spectrum that a hydrophilic carboxyl group was introduced into a carbon nanotube.

(2) Esterification

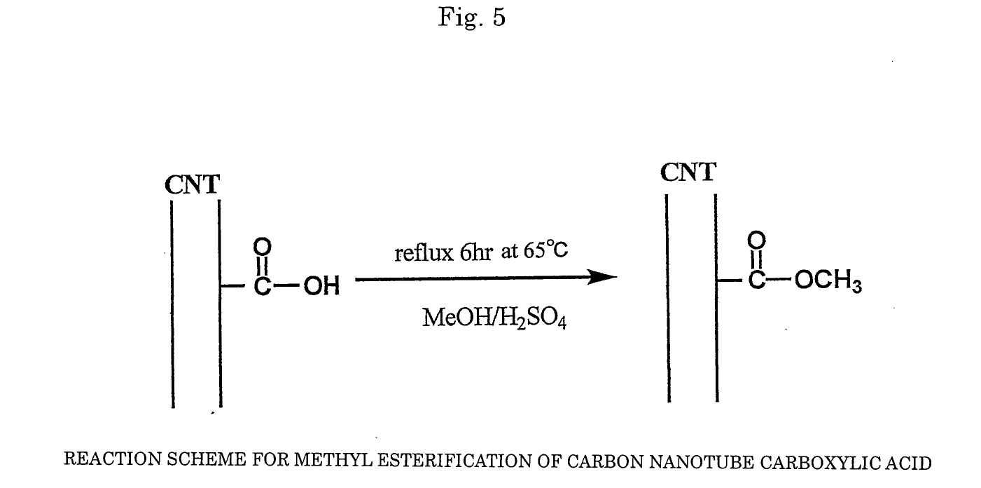

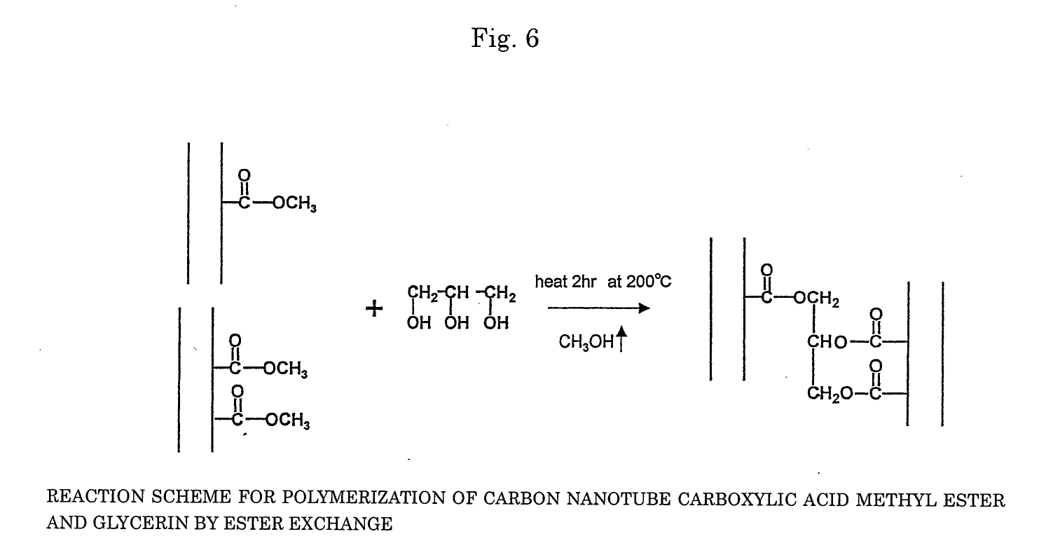

30 mg of the carbon nanotube carboxylic acid prepared in the above step is added to 25 ml of methanol (available from Wako Pure Chemical Industries, Ltd.). Then, 5 ml of concentrated sulfuric acid (98 mass %, available from Wako Pure Chemical Industries, Ltd.) was added, and reflux was conducted at 65° C. for 6 hours for methyl esterification. The reaction scheme for the above-mentioned methyl esterification is shown in FIG. 5.

After the temperature of the liquid solution had been recovered to room temperature, the liquid solution was filtered to separate a precipitate. The precipitate was washed with water, and was then recovered. An infrared absorption spectrum of the recovered precipitate was measured. As a result, absorption at 1,735 cm⁻¹ and that in the range of 1,000 to 1,300 cm⁻¹ characteristic of ester were observed. This result confirmed that the carbon nanotube carboxylic acid was esterified.

(Mixing Step)

30 mg of the carbon nanotube carboxylic acid methyl esterified in the above step was added to 4 g of glycerin (available from KANTO KAGAKU) and was mixed using an ultrasonic disperser. Further, the mixture was added to 4 g of methanol as a viscosity adjuster to prepare a cross-linking application liquid (1).

(A-3) Applying Step

The cross-linking application liquid 11 (1 μl) prepared in Step (A-1) was applied in a linear shape (having a width of 2 mm and a thickness of 1 μm) to a Kapton® tape 2 having a width of 5 mm.

(B) Cross-Linking Step

After the cross-linking application liquid had been applied, the tape 2 having formed thereon the coat was heated for 2 hours at 200° C. while being heated to cure the coat, thereby resulting in the carbon nanotube structure layer 1.

The condition of the resultant carbon nanotube structure layer 1 was observed using an optical microscope. As a result, an extremely uniform cured film was obtained, and a wire in which a nanotube structure was configured was obtained.

(Verification Experiment)

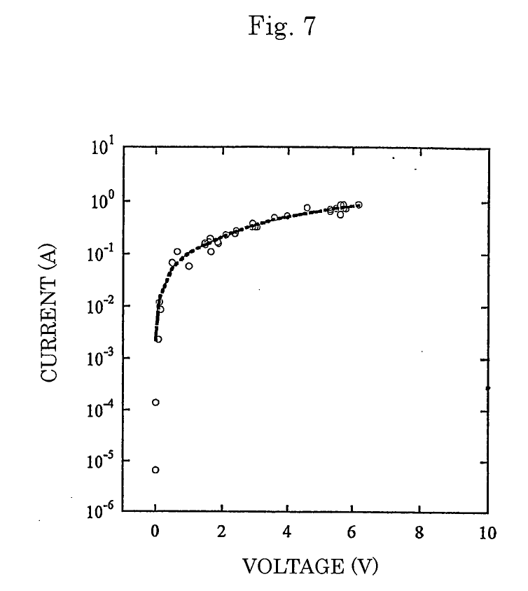

The current-voltage measurement of the wire obtained in Example 1 was performed to confirm that a current with a current density of 4×10⁴ A/cm² flowed (FIG. 7). The value is comparable to four times a critical current density of a superconductor (in general of the order of 10,000 A/cm²). An electromagnet was fabricated by using the wire. The wire was wound about an iron cylinder 82 with a diameter of 3 cm and a length of 10 cm at 50 turns/10 cm to fabricate an electromagnet. A current of 0.1 A was passed through the wire, and the magnetic field strength directly above the electromagnet was measured with a gaussmeter to confirm that a magnetic field with a magnetic field strength H of 160 A/m was generated.

As described above, according to the present invention, the wire which is excellent in electric conductivity or mechanical properties and in which bonding between carbon nanotubes is established with reliability is obtained, so that characteristics of the carbon nanotube can be effectively utilized. In addition, the electromagnet that is tough against winding, hardly breaks, and is stable can be obtained.

1. A wire comprising a core wire of a carbon nanotube structure in which functional groups bonded to plural carbon nanotubes are chemically bonded and mutually cross-linked to configure a mesh structure.

2. A wire according to claim 1, wherein the carbon nanotube structure is produced by curing a liquid solution containing plural carbon nanotubes to which functional groups are bonded, and by chemically bonding together the plural functional groups bonded to the carbon nanotubes to form a cross-linked site.

3. A wire according to claim 2, wherein:
each of the cross-linked sites has a structure, in which the plural functional groups are cross-linked together through a cross-linking agent in the liquid solution; and
the cross-linking agent is a not self-polymerizable cross-linking agent.

4. A wire according to claim 1, wherein each of the cross-linked sites, where the plural carbon nanotubes are cross-linked to one another, has at least one chemical structure selected from the group consisting of —COO(CH₂)₂OCO—, —COOCH₂CHOHCH₂OCO—, —COOCH₂CH(OCO—)CH₂OH, and —COOCH₂CH(OCO—)CH₂OCO.

5. A wire according to claim 2, wherein the cross-linked sites are formed through chemical bonds of the plural functional groups.

6. A wire according to claim 5, wherein a reaction forming the chemical bonds is at least one reaction selected from the group consisting of a dehydration condensation, a substitution reaction, an addition reaction, and an oxidative reaction.

7. A wire according to claim 1, wherein each of the cross-linked sites, where the plural carbon nanotubes are cross-linked to one another, has at least one chemical structure selected from the group consisting of —COOCO—, —O—, —NHCO—, —COO—, —NCH—, —NH—, —S—, —O—, —NHCOO—, and —S—S—.

8. A wire according to claim 1, wherein the plural carbon nanotubes are multi-wall carbon nanotubes.

9. A wire according to claim 1, further comprising a coating arranged on a periphery of the core wire of the carbon nanotube structure.

10. A method of manufacturing a wire, comprising:
applying a base body surface with a liquid solution containing plural carbon nanotubes that have plural functional groups bonded thereto; and
cross-linking the plural carbon nanotubes to one another through chemical bonding the plural functional groups together to form a core wire layer of a carbon nanotube structure to configure a mesh structure.

11. A method of manufacturing a wire according to claim 10, wherein the liquid solution includes a cross-linking agent that cross-links the plural functional groups together, and wherein the cross-linking agent is a not self-polymerizable cross-linking agent.

12. A method of manufacturing a wire according to claim 11, wherein:
each of the functional groups is at least one functional group selected from the group consisting of —OH, —COOH, —COOR (R is a substituted or unsubstituted hydrocarbon group), —COX (X is a halogen atom), —NH₂, and —NCO; and
the cross-linking agent is capable of prompting a cross-linking reaction with the selected functional groups.

13. A method-of manufacturing a wire according to claim 11, wherein:
the cross-linking agent is at least one cross-linking agent selected from the group consisting of polyol, polyamine, polycarboxylic acid, polycarboxylate, polycarboxylic acid halide, polycarbodiimide, and polyisocyanate; and
the functional groups are capable of prompting a cross-linking reaction with the selected cross-linking agent.

14. A method of manufacturing a wire according to claim 11, wherein:
each of the functional groups is at least one functional group selected from the group consisting of —OH, —COOH, —COOR (R is a substituted or unsubstituted hydrocarbon group), —COX (X is a halogen atom), —NH₂, and —NCO;
the cross-linking agent is at least one cross-linking agent selected from the group consisting of polyol, polyamine, polycarboxylic acid, polycarboxylate, polycarboxylic acid halide, polycarbodiimide, and polyisocyanate; and
the functional groups and the cross-linking agents are respectively selected for a combination capable of prompting a cross-linking reaction with one another.

15. A method of manufacturing a wire according to claim 12, wherein each of the functional group is —COOR (R is a substituted or unsubstituted hydrocarbon group).

16. A method of manufacturing a wire according to claim 15, wherein the cross-linking agent is polyol.

17. A method of manufacturing a wire according to claim 15, wherein the cross-linking agent is glycerin and/or ethylene glycol.

18. A method of manufacturing a wire according to claim 10, wherein the liquid solution further includes a solvent.

19. A method of manufacturing a wire according to claim 18, wherein the cross-linking agent also functions as a solvent.

20. A method of manufacturing a wire according to claim 10, wherein a reaction forming the chemical bonds is a reaction for chemical bonding the plural functional groups together.

21. A method of manufacturing a wire according to claim 20, wherein the liquid solution further includes an additive that forms the chemical bonds among the functional groups.

22. A method of manufacturing a wire according to claim 21, wherein the reaction is a dehydration condensation and the additive is a condensing agent.

23. A method of manufacturing a wire according to claim 22, wherein each of the functional groups is at least one functional group selected from the group consisting of —COOR (R is a substituted or unsubstituted hydrocarbon group), —COOH, —COX (X is a halogen atom), —OH, —CHO—, and —NH₂.

24. A method of manufacturing a wire according to claim 23, wherein each of the functional groups is —COOH.

25. A method of manufacturing a wire according to claim 22, wherein the condensing agent is at least one condensing agent selected from the group consisting of sulfuric acid, N-ethyl-N′-(3-dimethylaminopropyl)carbodiimide, and dicyclohexyl carbodiimide.

26. A method of manufacturing a wire according to claim 21, wherein the reaction is a substitution reaction and the additive is a base.

27. A method of manufacturing a wire according to claim 26, wherein each of the functional groups is at least one functional group selected from the group consisting of —NH₂, —X (X is a halogen atom), —SH, —OH, —OSO₂CH₃, and —OSO₂(C₆H₄)CH₃.

28. A method of manufacturing a wire according to claim 26, wherein the base is at least one base selected from the group consisting of sodium hydroxide, potassium hydroxide, pyridine, and sodium ethoxide.

29. A method of manufacturing a wire according to claim 20, wherein the reaction is an addition reaction.

30. A method of manufacturing a wire according to claim 29, wherein each of the functional groups is —OH and/or —NCO.

31. A method of manufacturing a wire according to claim 20, wherein the reaction is an oxidative reaction.

32. A method of manufacturing a wire according to claim 31, wherein each of the functional groups is —SH.

33. A method of manufacturing a wire according to claim 31, wherein the liquid solution further includes an oxidative reaction accelerator.

34. A method of manufacturing a wire according to claim 33, wherein the oxidative reaction accelerator is iodine.

35. An electromagnet constructed by winding the wire according to claim 1 in a coil shape.
